(19) United States
(12) Patent Application Publication
(10) Pub. No.: US 2006/0163656 A1
(43) Pub. Date: Jul. 27, 2006

(54) Nonvolatile memory device with curved floating gate and method of fabricating the same

(75) Inventor: Ji-Woon Rim, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/338,470

(22) Filed: Jan. 24, 2006

(30) Foreign Application Priority Data
Jan. 25, 2005 (KR) 10-2005-0006834

(51) Int. Cl. H01L 21/336; H01L 27/12

(52) U.S. Cl. 257/350; 438/257

(57) ABSTRACT

Disclosed is a nonvolatile memory device comprising: a tunnel oxide layer on a semiconductor substrate; a floating gate on the tunnel oxide layer; a gate interlevel insulation layer on the floating gate layer; a control gate on the gate interlevel insulation layer; a source region at a side of the floating gate in the semiconductor substrate; and a drain region at the other side of the floating gate in the semiconductor substrate. The floating gate comprises a first side adjacent to the source region and a second side adjacent to the wordline and not to the source region. The first face is curved.

### CROSS-REFERENCE TO RELATED APPLICATIONS

This U.S. non-provisional patent application claims priority under 35 U.S.C. § 119 of Korean Patent Application 2005-06834 filed on Jan. 25, 2005, the entire contents of which are hereby incorporated by reference.

### BACKGROUND

The invention described herein is related to semiconductor memory devices, and, in particular, relates to a nonvolatile memory device having curved floating gates. The invention described herein also relates to a method of fabricating the nonvolatile memory device having curved floating gates.

Flash memory devices, a type of nonvolatile memory devices, have unit cells each of which includes a floating gate to store data and a control gate to regulate operations of programming, reading and erasing. Usually, the nonvolatile flash memory devices are classified into the types of split gate and stacked gate flash memory devices.

FIG. 1 is a plane view of a conventional nonvolatile memory device with a split gate structure. FIG. 2 is a sectional view taken along the line I-I′ of FIG. 1.

Referring to FIGS. 1 and 2, field isolation layers Fox define active regions in a semiconductor substrate 1. Wordlines (WL) 11 cross over the field isolation layers Fox. A floating gate (FG) 5 is partially disposed between the wordline 11 and the semiconductor substrate 1. A tunnel oxide layer 3 is interposed between the floating gate 5 and the semiconductor substrate 1. A gate interlevel insulation layer 9 is interposed between the wordline 11 and the semiconductor substrate 1, and between the wordline 11 and the floating gate 5. An oxide layer 7 is disposed on the floating gate 5 to shape the top edges of the floating gate 5 to have sharpened tips. A common source line (CSL) 13a is located at the active region near the floating gate 5, among the active regions, while a drain region (D) 13b is located at the opposite active region of the common source line 13a. Although not shown, the drain region 13b is associated with a bitline contact that is coupled to a bitline arranged to cross over the wordline 11. The floating gate 5 is generally designed in the pattern of a regular square or rectangular form in plan view. However, the practical pattern of the floating gate results in a round tetragon due to the proximity effect in a photolithography process.

Referring to FIGS. 1 and 2, in programming the nonvolatile split-gate memory device, a high voltage is applied to the common source line (CSL) 13a while a low voltage is applied to the drain region (D) 13b. The wordline (WL) 11 may be coupled to a voltage lower than the voltage applied to the drain region 13b. As a result, the floating gate 5 is programmed by means of hot carriers. Applying the high voltage to the common source line (CSL) 13a, although not shown, may be carried out through a contact plug disposed at the end of the common source line 13a. However, although the high voltage is applied to the end of the common source line (CSL) 13a, voltage is gradually decreased along a distance from the first supply position thereof due to sheet resistance according to a length of the common source line. As a result, a floating gate, spaced apart from the first supply position of the high voltage, would not be programmed because of absence of an effective voltage level at the floating gate. As semiconductor devices are being highly integrated, the sheet resistance on the common source line increases along with narrower dimensions in intervals between the wordlines and the floating gates. So, the problems associated with voltage drop by the linear supplies of the high voltages along the common source lines in the split-gate memory devices are increasing.

### SUMMARY OF THE INVENTION

The invention is directed to a nonvolatile memory device and method of fabricating the same, capable of enhancing the efficiency of programming data.

The invention is also directed to a nonvolatile memory device and method of fabricating the same, capable of enhancing the efficiency of erasing data.

According to one aspect, the invention is directed to a nonvolatile memory device comprising: a tunnel oxide layer on a semiconductor substrate; a floating gate on the tunnel oxide layer; a gate interlevel insulation layer on the floating gate; a control gate on the gate interlevel insulation layer; a source region at a side of the floating gate in the semiconductor substrate; and a drain region at the other side of the floating gate in the semiconductor substrate. The floating gate comprises a first face adjacent to the source region and a second face adjacent to the drain region. The first face is curved toward the drain region.

The device may be configured as a split-gate type device. In this case, the second face is curved, and, in one embodiment, is curved toward the drain region. Alternatively, the second face is curved toward the source region. The control gate can include a third face adjacent to the source region and a fourth face adjacent to the drain region. The fourth face is curved along a profile of the second face.

The device may be configured as a stacked-gate type device. The control gate can include a third face adjacent to the source region and a fourth face adjacent to the drain region. The third face is aligned to the first face and the fourth face is aligned to the second face. The second face is curved and, can be curved toward the drain region or source region.

The nonvolatile memory device may further comprise an HSG film formed at top edges of the floating gate.

According to another aspect, the invention is directed to a method of fabricating a nonvolatile memory device. The nonvolatile memory device can be a split-gate nonvolatile memory device. According to the method, field isolation layers are formed in a semiconductor substrate to define active regions. A tunnel oxide layer is formed on the active regions. A floating-gate layer is formed over the semiconductor substrate. A hard mask with openings is formed to partially expose the floating-gate layer. The floating-gate layer is partially oxidized through the openings to form a mask oxide layer. The hard mask is removed. The floating-gate layer is etched using the mask oxide layer as an etch mask to form a floating gate. A gate interlevel insulation layer is formed to cover the floating gate. A control gate layer is formed, and the control gate layer is etched to form a control gate that covers a partial top and sidewall of the floating gate and a part of the active region. A source region is formed at a side of the floating gate in the semiconductor substrate, and a drain region is formed at the other side of the floating gate in the semiconductor substrate. The floating gate comprises a first face adjacent to the source region, the first face being curved and being recessed to the drain region.

The method can further comprise, before forming the hard mask, forming an HSG film on the floating-gate layer.

According to another aspect, the invention is directed to a method of fabricating a nonvolatile memory device. The nonvolatile memory device can be a stacked-gate nonvolatile memory device. Field isolation layers are formed in a semiconductor substrate to define active regions. A tunnel oxide layer is formed on the active regions. A floating-gate layer is formed over the semiconductor substrate. The floating-gate layer is patterned to expose the field isolation regions. A gate interlevel insulation layer and a control gate layer are formed over the semiconductor substrate. The control gate layer, the gate interlevel insulation layer, and the floating-gate layer are sequentially patterned to form a wordline crossing over the field isolation layers and a floating gate under the wordline. A source region is formed at a side of the floating gate in the semiconductor substrate, and a drain region is formed at the other side of the floating gate in the semiconductor substrate. The floating gate comprises a first face adjacent to the source region, and the first face is curved and recessed to the drain region.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 is a plan view of a conventional nonvolatile memory device with a split gate structure.

FIG. 2 is a sectional view taken along line I-I′ of FIG. 1.

FIG. 3A is a plan view illustrating a nonvolatile memory device with a split gate structure in accordance with an embodiment of the invention.

FIG. 3B is a sectional view taken along line II-II′ of FIG. 3A.

FIG. 3C is a sectional view taken along line III-III′ of FIG. 3A.

FIG. 3D is an enlarged view illustrating part B of FIG. 3A.

FIG. 3E is a perspective view illustrating a unit cell of FIG. 3A.

FIGS. 4A, 5A, 6A, and 7A are plan views showing sequential processing steps for fabricating the nonvolatile memory device of FIG. 3A.

FIGS. 4B, 5B, 6B, and 7B are sectional views showing sequential processing steps in correspondence with the view of FIG. 3B, taken along lines II-II′ of FIGS. 4A, 5A, 6A, and 7A (same as the line II-II′ of FIG. 3A), respectively.

FIGS. 4C, 5C, 6C, and 7C are sectional views showing sequential processing steps in correspondence with the view of FIG. 3B, taken along lines III-III′ of FIGS. 4A, 5A, 6A, and 7A (same as the line III-III′ of FIG. 3A), respectively.

FIGS. 8 through 11 are plan views illustrating unit cells of the nonvolatile memory devices having split gates in accordance with embodiments of the invention.

FIG. 12A is a plan view illustrating a nonvolatile memory device with a split gate structure in accordance with another embodiment of the invention.

FIG. 12B is a sectional view taken along with the line II-II′ of FIG. 12A.

FIG. 12C is a sectional view taken along with the line III-III′ of FIG. 12A.

FIG. 13A is an enlarged detailed plan view showing a method of fabricating the nonvolatile memory device of FIG. 12A.

FIG. 13B is a sectional view showing a method of fabricating the nonvolatile memory device in correspondence with the feature of FIG. 12B, taken along line II-II′ of FIG. 13A.

FIG. 13C is a sectional view showing a method of fabricating the nonvolatile memory device in correspondence with the feature of FIG. 12C, taken along line III-III′ of FIG. 13A.

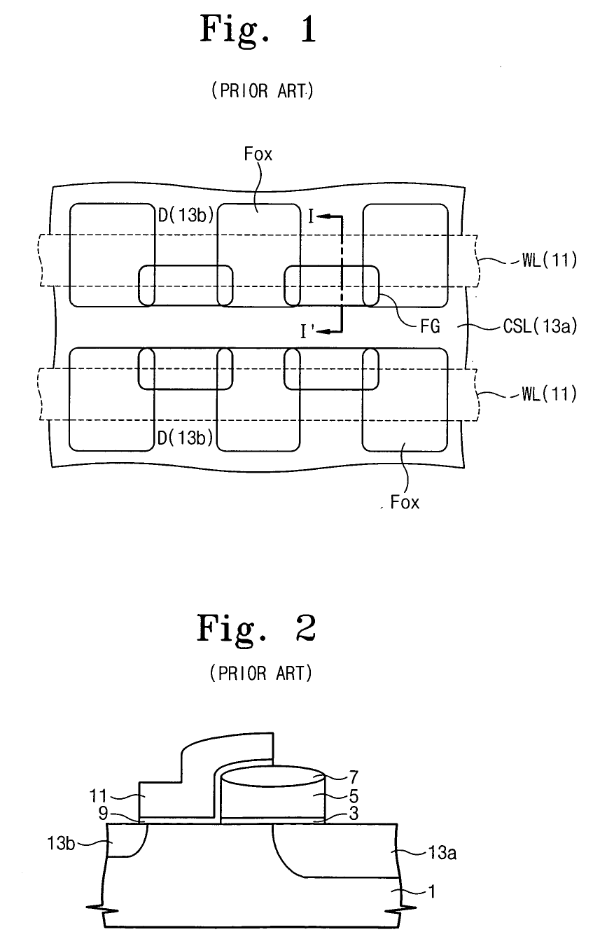

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the invention to those skilled in the art. For instance, the nonvolatile memory device by the embodiment is described for a NOR-type flash memory device, but may be available for a NAND-type flash memory device.

It will be understood that when a layer is referred to as being on another layer or substrate, it can be directly on the other layer or substrate, or intervening layers may also be present. In this description, wordline means the same as control gate.

Hereinafter, an exemplary embodiment of the present invention in conjunction with the accompanying drawings will be described.

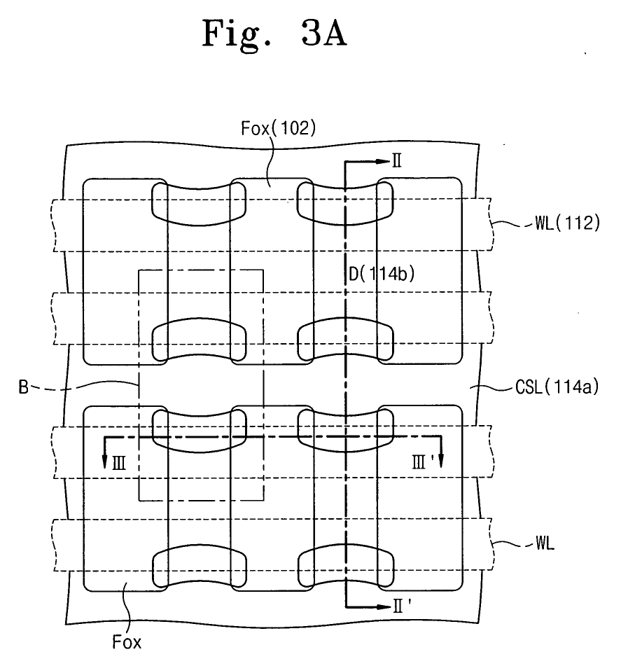

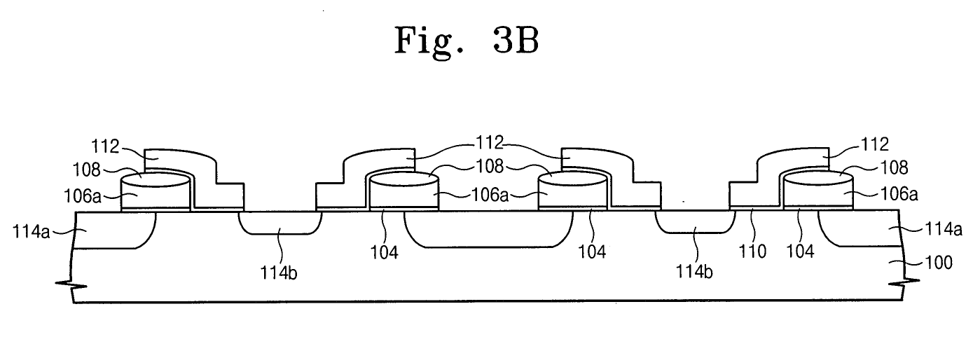

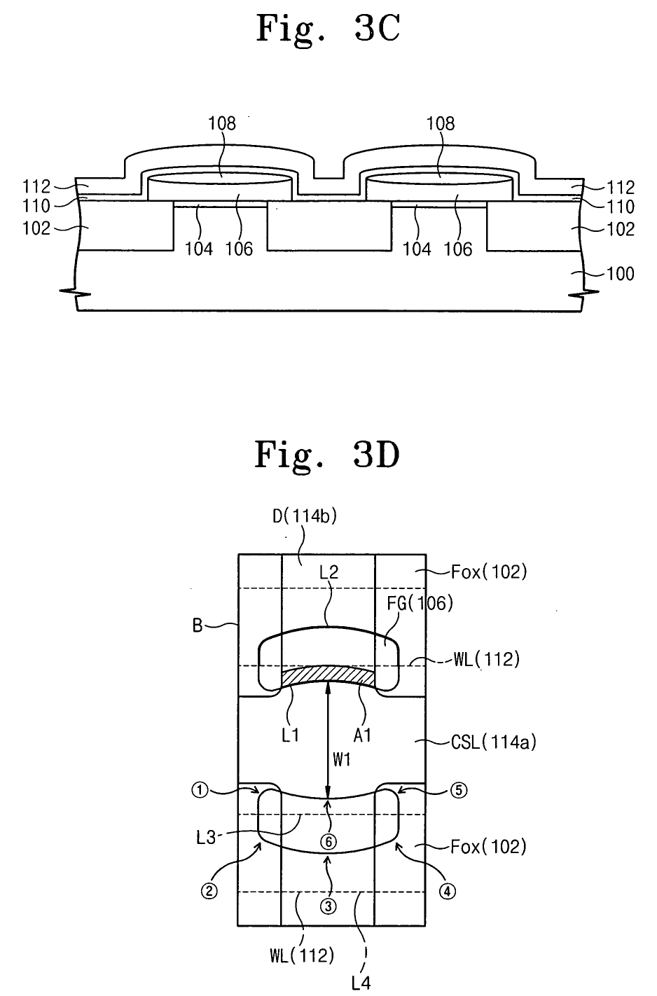

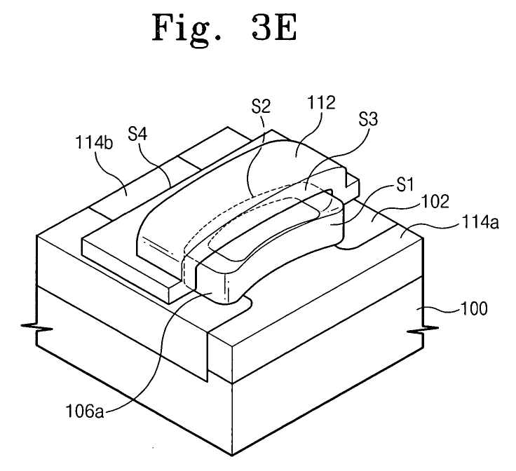

FIG. 3A illustrates a top view of a nonvolatile memory device with a split-gate structure in accordance with an embodiment of the invention. FIG. 3B is a sectional view taken along line II-II′ of FIG. 3A. FIG. 3C is a sectional view taken along line III-III′ of FIG. 3A. FIG. 3D is a detailed enlarged view of the portion labeled B of FIG. 3A. FIG. 3E perspectively illustrates a unit cell of FIG. 3A.

Referring to FIGS. 3A, 3B, 3C, 3D, and 3E, field isolation layers Fox define active regions in a semiconductor substrate 100. Wordlines (WL; control gate lines) 112 cross over the field isolation layers Fox on the semiconductor substrate 10Q. A floating gate (FG) 106 is partially disposed between the wordline 112 and the semiconductor substrate 100. A tunnel oxide layer 104 is interposed between the floating gate 106 and the semiconductor substrate 100. A gate interlevel insulation layer 110 is interposed between the wordline 112 and the semiconductor substrate 100, and between the wordline 112 and the floating gate 106. The gate interlevel insulation layer 110 may include a single layer of an oxide or nitride layer, or a dual layer. On the floating gate 106, an oxide layer 108 is disposed to make the top edges of the floating gate 106 be shaped to have sharpened tips. A common source line (CSL) 114a is located at the active region near the floating gate 106, among the active regions, while a drain region (D) 114b is located at the active region opposite to the common source line 114a. Although not shown, the drain region 114b is associated with a bitline contact that is coupled to a bitline arranged crossing over the wordline 112.

The floating gate (FG) 106 is comprised of a first face SI (see FIG. 3E) and a first side L1 (see FIG. 3D) that are adjacent to the common source line (CSL) 114a, and a second face S2 (see FIG. 3E) and a second side L2 (see FIG. 3D) that are adjacent to the wordline (WL) 112 not to the common source line 114a. The first face and side, S1 and L1, are curved and recessed to the wordline (WL) 112. The second face and side, S2 and L2, are curved and recessed to the drain region (D) 114b. The floating gate (FG) 106 has six curved positions \textcircled{1}˜\textcircled{6} therearound. As the first face S1 of the floating gate 106, i.e., the first side L1, is curved toward the wordline 112, a width W1 between the adjacent floating gates 114a becomes larger. Thereby, the overall area of the common source line 114a extends to reduce the sheet resistance. Since the floating gate 106 is formed by way of an etching process, the horizontal profile of the first face SI is identical to that of the first side L1 and the horizontal profile of the second face S2 is identical to that of the second side L2. The wordline 112 is comprised of a third face S3 (see FIG. 3E) and a third side L3 (see FIG. 3D) that are adjacent to the common source line 114a, and a fourth face S4 (see FIG. 3E) and a fourth side L4 (see FIG. 3D) that are adjacent to the drain region 114b. Since the wordline 112 is also formed by way of an etching process, the horizontal profile of the third face S3 is identical to that of the third side L3 and the horizontal profile of the fourth face S4 is identical to that of the fourth side L4. In this embodiment, the third face and side, S3 and L3, are configured in linear patterns.

Both sides of a general floating gate, corresponding to the first and second sides, L1 and L2, are configured in linear patterns. But, the floating gate 106 is longer than a conventional floating gate because the first and second sides L1 and L2 are curved not be linear within a given area. Therefore, the curved profile of the first side L1 enlarges an area A1 overlapped by the floating gate (FG) 106 and the common source line (CSL) 114a, larger than the conventional case. If the overlapped area A1 enlarges, it increases a coupling ratio between the floating gate 106 and the common source line 114a. As a result, it is possible to shorten a programming time and to enhance the programming efficiency.

Also, since the second side L2 of the floating gate 106 is curved to be longer than the conventional floating gate, it is possible to shorten an erasing time and to improve the erasing efficiency for the nonvolatile memory device. Further, as the edge of the floating gate, contacting to the field isolation region, becomes longer, it is able to prevent leakage current therein.

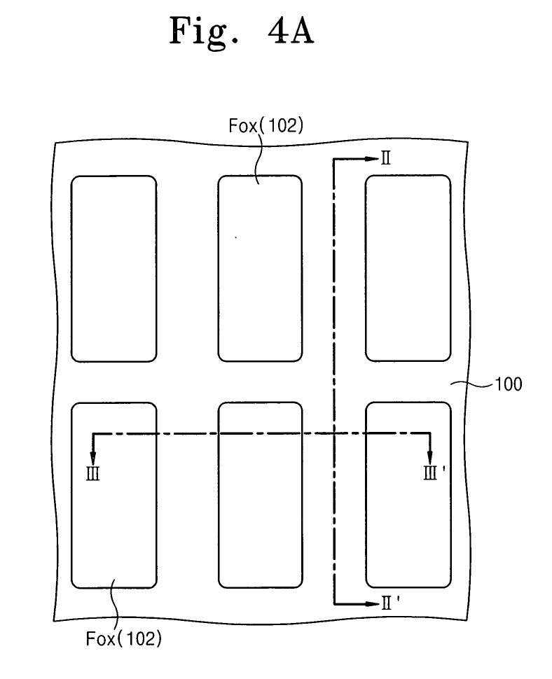

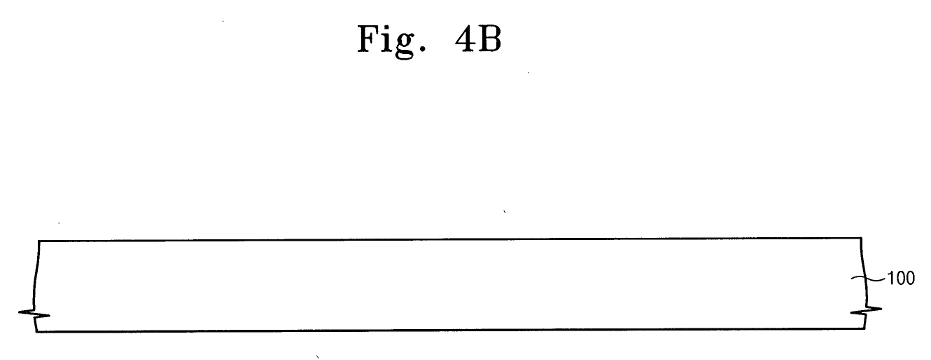

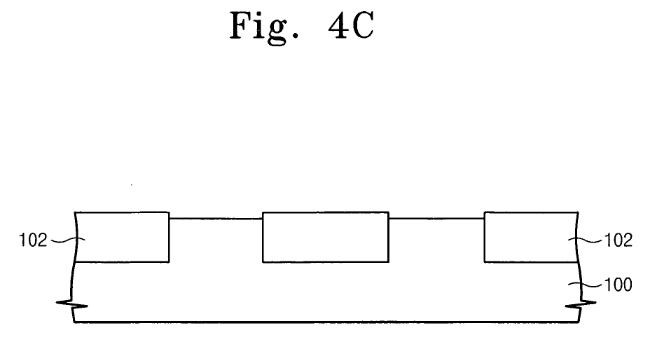

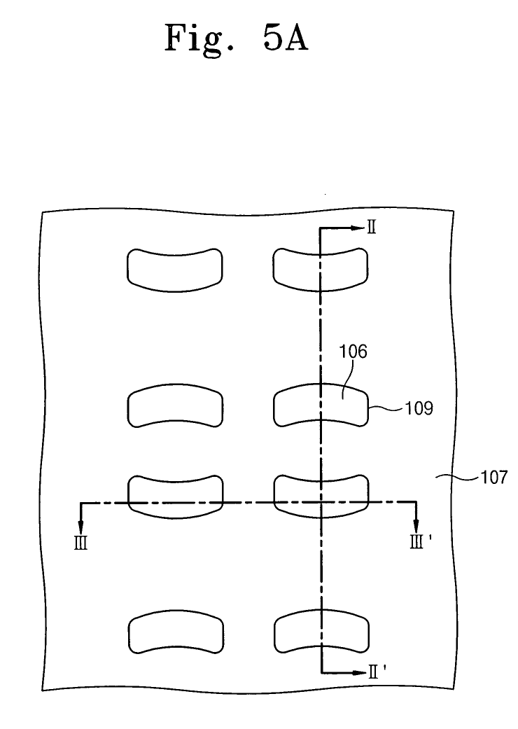

FIGS. 4A, 5A, 6A, and 7A are plan views showing sequential processing steps for fabricating the nonvolatile memory device of FIG. 3A. FIGS. 4B, 5B, 6B, and 7B are sectional views showing sequential processing steps in correspondence with the view of FIG. 3B, taken along line II-II′ of FIGS. 4A, 5A, 6A, and 7A (same as the line II-II′ of FIG. 3A), respectively. FIGS. 4C, 5C, 6C, and 7C are sectional views showing sequential processing steps in correspondence with the view of FIG. 3C, taken along line III-III′ of FIGS. 4A, 5A, 6A, and 7A (same as the line III-III′ of FIG. 3A), respectively.

Referring to FIGS. 4A, 4B, and 4C, the field isolation layers (Fox) 102 are formed in the semiconductor substrate 100. The field isolation layers 102 may be constructed of oxide or nitride layers by means of the shallow trench isolation (STI) processing technique.

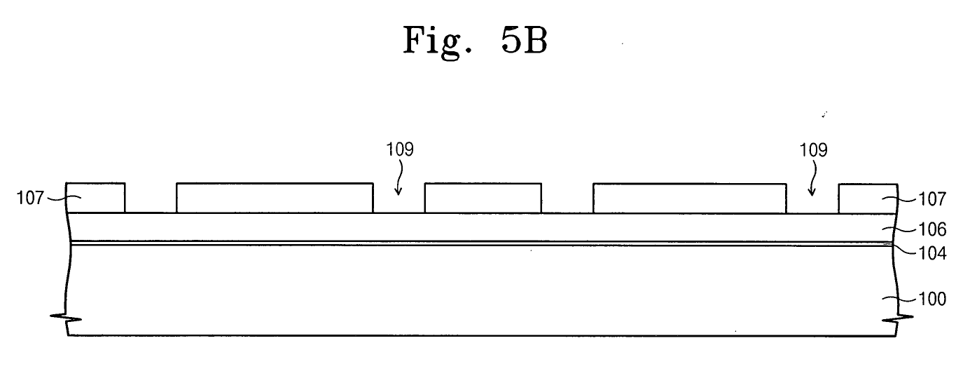

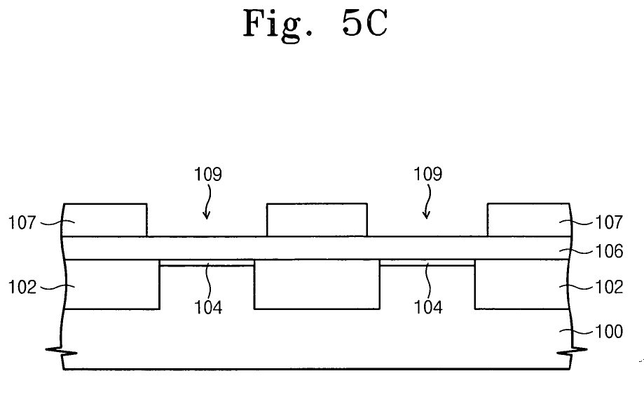

Referring to FIGS. 5A, 5B, and 5C, the tunnel oxide layer 104 is formed by conducting a thermal oxidation process for the semiconductor substrate 100 including the field isolation layers 102. A floating-gate layer 106 is deposited on the semiconductor substrate 100 including the tunnel oxide layer 104. The floating-gate layer 106 may be formed of an impurity-doped polysilicon layer as an example. A hard mask layer 107 of silicon nitride is set on the floating-gate layer 106, having openings 109 as shown in FIG. 5A. The openings 109 are configured to define the shapes of the floating gates FG, partially exposing the floating-gate layer 106 over and between the field isolation layers (Fox) 102 as shown in FIG. 5C.

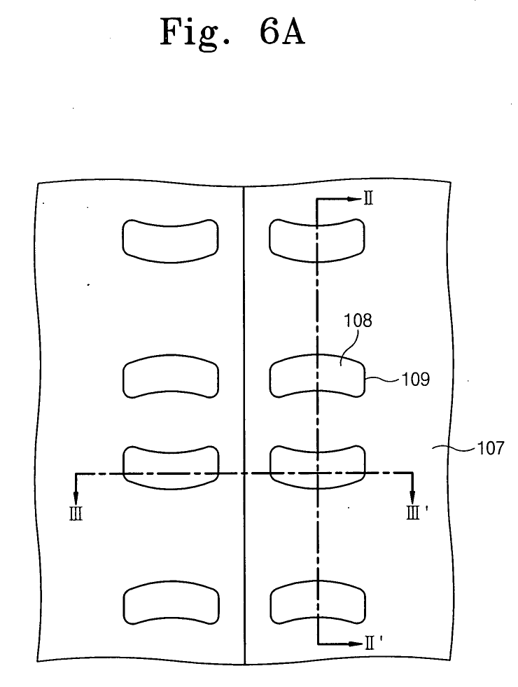

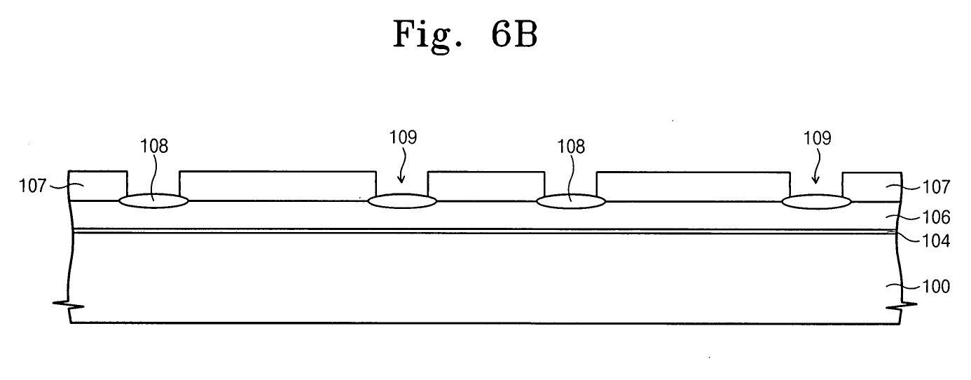

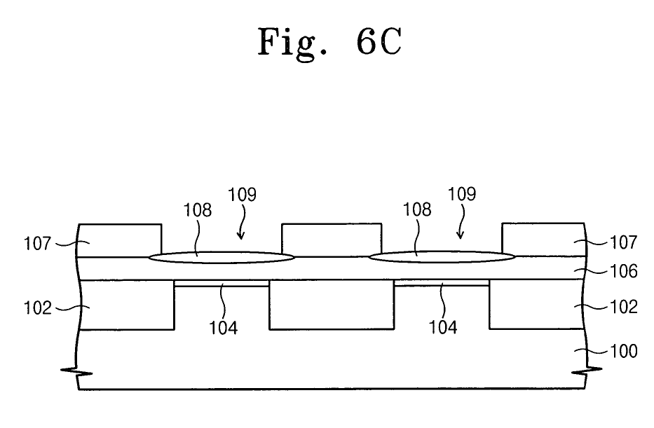

Referring to FIGS. 6A, 6B, and 6C, a thermal oxidation process is carried out to oxidize the floating-gate layer 106 partially exposed by the openings 109. Thus mask oxide layers 108 are formed at the openings 109 that are the exposed portions of the floating-gate layer 106. The mask oxide layer 108 is configured with thicker center and thinner edges giving the effect of a bird's beak.

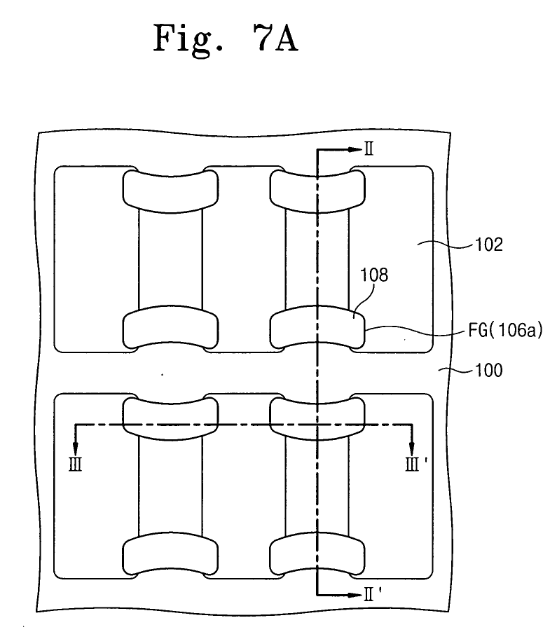

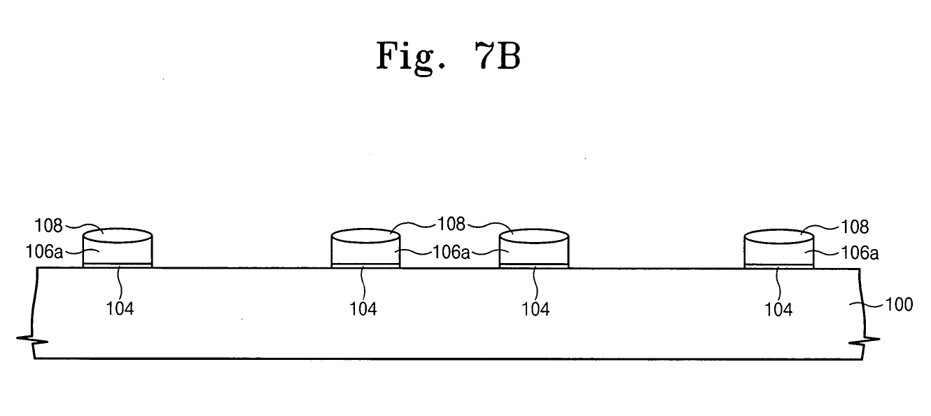

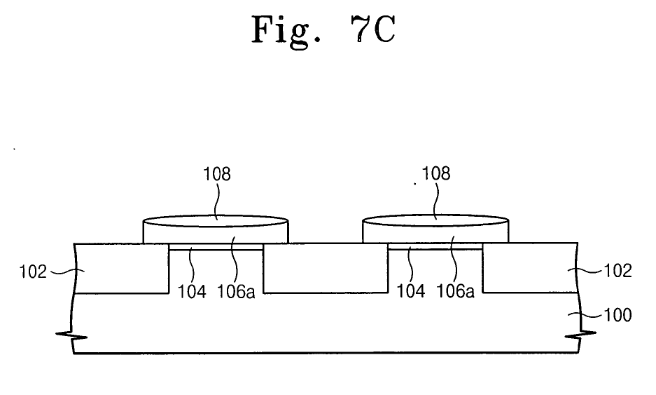

Referring to FIGS. 7A, 7B, and 7C, after removing the hard mask layer 107, the floating-gate layer 106 is partially exposed, with the exception of the portions covered by the mask oxide layers 108. The floating-gate layer 106 is etched using the pattern of the mask oxide layers 108 as an etch mask, so that the semiconductor substrate 100 is partially exposed and the pattern of the floating gates 106a is completed therein. The edges of the floating gates 106a are positioned on the field isolation layers 102.

Subsequently, referring to FIGS. 3A, 3B, and 3C again, the floating gates 106a and the active regions are partially exposed by depositing and patterning the gate interlevel insulation layer 110 and the control gate layer 112, and the wordline (WL) 112 is formed intersecting the field isolation layers (Fox) 102. Thereafter, the common source line (CSL) 114a and the drain region (D) 114b are formed through ion implantation and thermal processing steps.

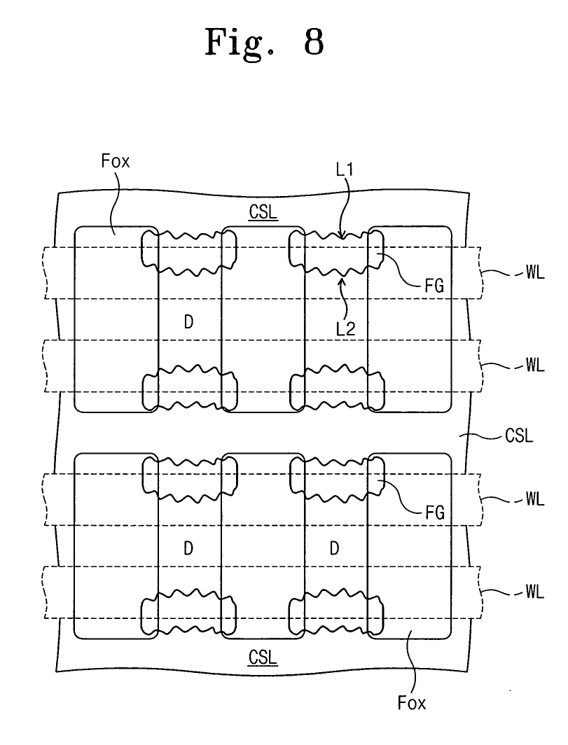

The configurations of the floating gate FG and the wordline WL may be modified to others as illustrated in FIGS. 8 through 11. FIGS. 8 through 11 are plan views illustrating unit cells of the nonvolatile memory devices having split gates in accordance with embodiments by the invention.

Referring to FIG. 8, other components of the unit cell are the same as those of FIG. 3A, with the exception of the floating gate FG. In FIG. 8, the floating gate FG is comprised of many curved portions more than six in number. The floating gate FG embodied in FIG. 8 may be formed by patterning the opening 109 into the shape shown in FIG. 8. Alternatively, an HSG film can be formed over the floating-gate layer 106 before depositing the hard mask layer 107. With the hard mask layer 107 and the mask oxide layer 108, the top edges of the floating gate FG finally completed therein are configured in a rugged pattern by the addition of the HSG film. As a result, since the top edges of the floating gate FG become longer by the HSG film, it is possible to improve the erasing efficiency as mentioned above.

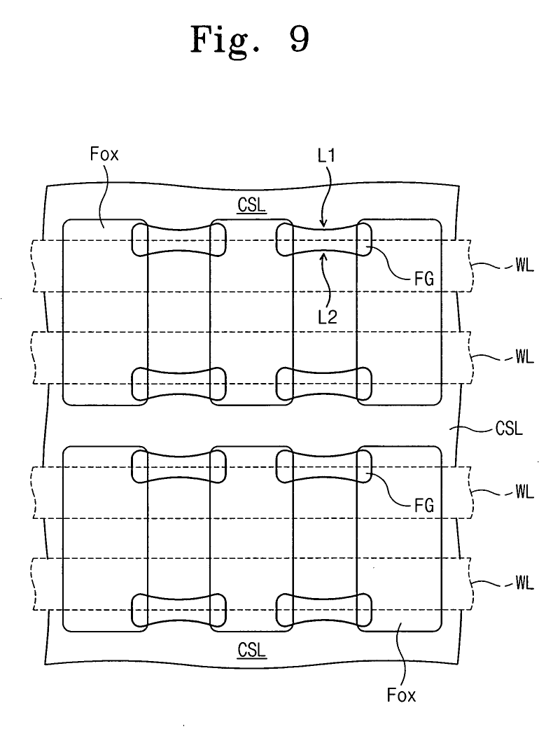

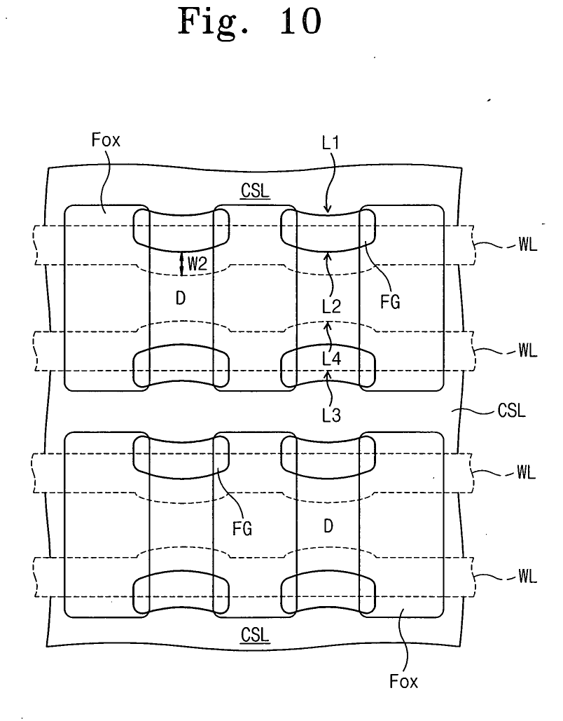

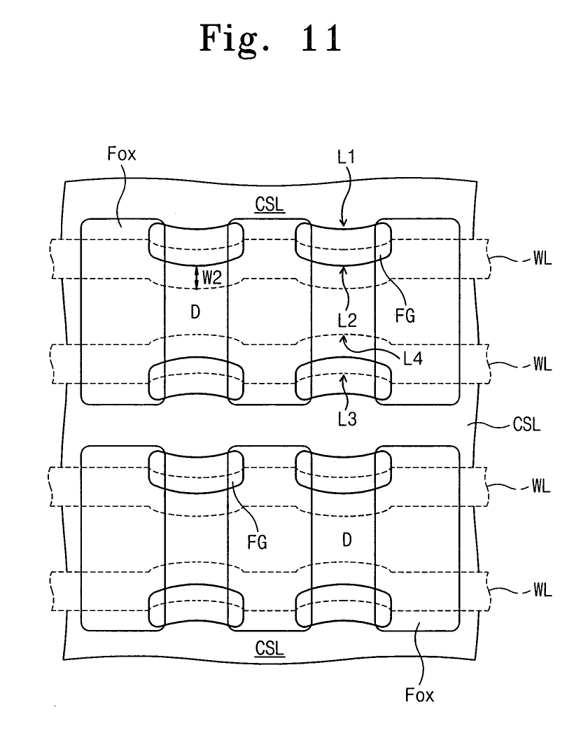

The second side L2, through which the floating gate FG contacts to the wordline WL, may be curved toward the common source line CSL as shown in FIG. 9. Thus, in the case of FIG. 9, the center of the floating gate FG is configured in a concave pattern. On the other hand, referring to FIG. 3A, the second side L2 of the floating gate FG is curved toward the drain region D while the wordline WL is configured to be linear, which may incur misalignment because of small processing margins when forming the wordline WL. The structures overcoming such misalignment are proposed in FIGS. 10 and 11, in which the side of the wordline not adjacent to the floating gate FG, i.e., the fourth side L4, is curved along the second side L2 of the floating gate FG. In FIG. 11, the side of the wordline adjacent to the floating gate FG, i.e., the third side L3, is curved along the first side L1 of the floating gate FG. As a result, the wordline WL has a width W2 not covering the floating gate FG.

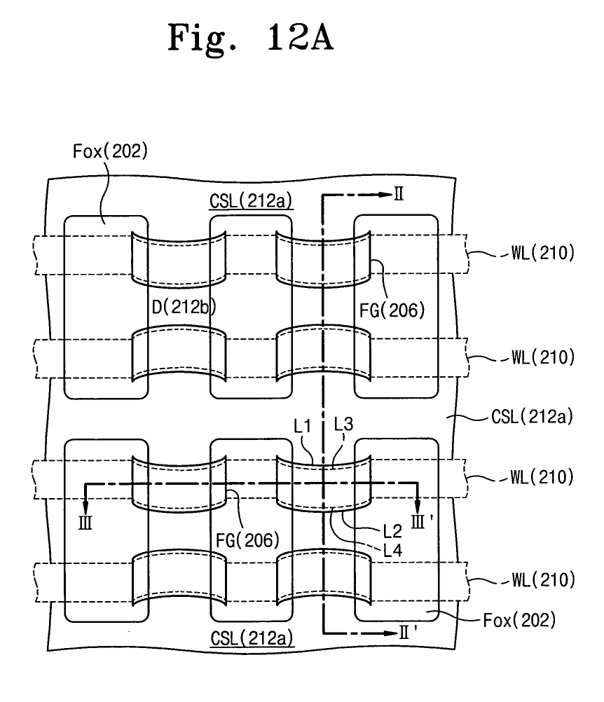

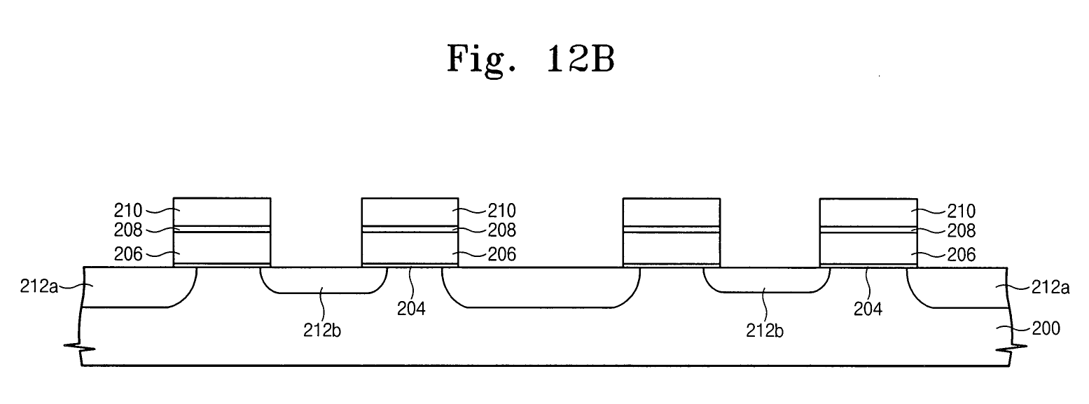

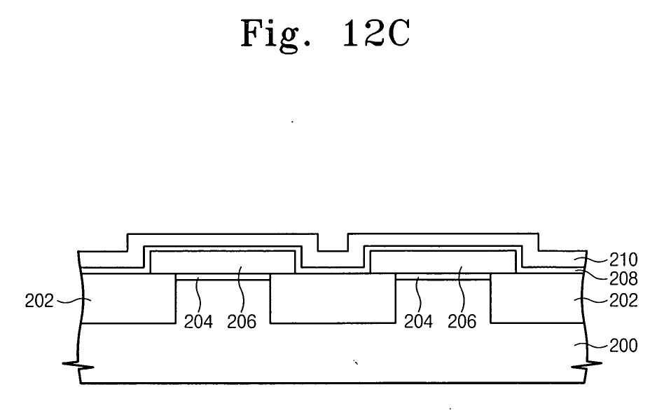

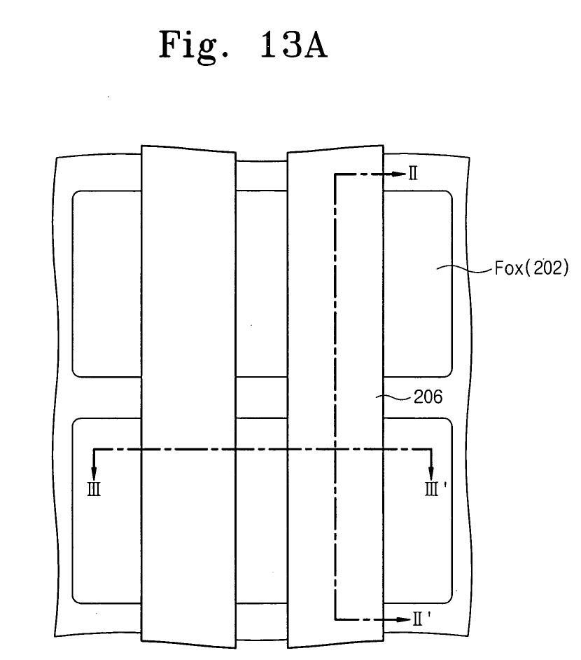

FIG. 12A is a plan view illustrating a nonvolatile memory device with a split-gate structure in accordance with another embodiment of the invention. FIG. 12B is a sectional view taken along line II-II′ of FIG. 12A. FIG. 12C is a sectional view taken along line III-III′ of FIG. 12A.

Referring to FIGS. 12A, 12B, and 12C, field isolation layers (Fox) 202 define active regions in a semiconductor substrate 200. Wordlines (WL; control gate lines) 210 cross over the field isolation layers 202 on the semiconductor substrate 200. A floating gate (FG) 206 is disposed between the wordline 210 and the semiconductor substrate 200. A tunnel oxide layer 204 is interposed between the floating gate 206 and the semiconductor substrate 200. A gate interlevel insulation layer 208 is interposed between the wordline 210 and the semiconductor substrate 200, and between the wordline 210 and the floating gate 206. A common source line (CSL) 212a is located at the active region near the wordline 210, while a drain region (D) 212b is located at the active region opposite to the common source line 212a. Although not shown, the drain region 212b is associated with a bitline contact that is coupled to a bitline arranged crossing over the wordline 210. The floating gate (FG) 206 is curved toward the drain region (D) 212b, rendering the common source line (CSL) 212a to be enlarged in width. The wordline (WL) 210 is also curved along the profile of the floating gate 206, and the sidewall of the wordline 210 is aligned to the sidewall of the floating gate 206. That is, the floating gate (FG) 206 is comprised of a first side L1 adjacent to the common source line (CSL) 212a and a second side L2 adjacent to the drain region (D) 212b, while the wordline (WL) 210 is comprised of a third side L3 adjacent to the common source line (CSL) 212a and a fourth side L4 adjacent to the drain region (D) 212b. The first side L1 is curved and recessed to the drain region 212b and the third side L3 accords to the profile of the first side L1. The second side L2 is curved recessed to the drain region 212b and the fourth side L4 accords to the profile of the second side L2.

As the stacked-gate nonvolatile memory device has the curved floating gate (FG) 206, the programming efficiency thereof can be enhanced as mentioned in conjunction with FIG. 3A.

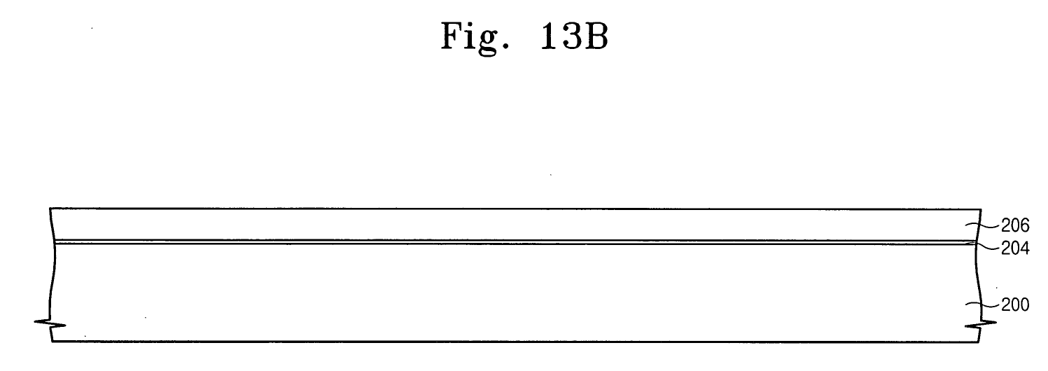

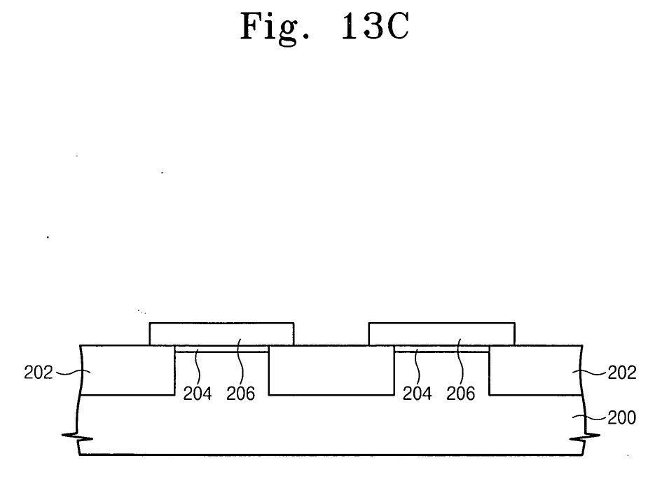

FIG. 13A is an enlarged detailed plan view showing a portion of a method of fabricating the nonvolatile memory device of FIG. 12A. FIG. 13B is a sectional view showing a portion of a method of fabricating the nonvolatile memory device in correspondence with the view of FIG. 12B, taken along line II-II′ of FIG. 13A. FIG. 13C is a sectional view showing a portion of a method of fabricating the nonvolatile memory device in correspondence with the view of FIG. 12C, taken along line III-III′ of FIG. 13A.

Referring to FIGS. 13A, 13B, and 13C, after forming the field isolation layers (Fox) 202 in the semiconductor substrate 200, as illustrated in FIGS. 4A, 4B, and 4C, the semiconductor substrate 200 is thermally oxidized to generate the tunnel oxide layer 204 on the active regions. The floating-gate layer 206 is stacked on the semiconductor substrate 200. The floating-gate layer 206 is patterned to partially expose the field isolation layers (Fox) 202 and to complete a floating-gate pattern 206b intersecting the active regions among the field isolation layers 202.

Subsequently, returning to FIGS. 12A, 12B, and 12C, the gate interlevel insulation layer 208 and the control gate layer (not shown) are formed entirely over the semiconductor substrate 200 by means of thermal and CVD processes. The control gate layer, the gate interlevel insulation layer 208, and the floating-gate pattern 206b are sequentially etched using a photoresist pattern (not shown) to form the wordline (WL) 210 and the floating gate (FG) 206 shown in FIG. 12A.

According to the invention, the nonvolatile memory device is comprised of the curved floating gates in their unit memory cells. As a result, sheet resistance of the common source line is reduced and the programming efficiency is enhanced. Furthermore, the face contacting with the wordline (i.e., the control gate) and the floating gate enlarges to improve the erasing efficiency for the nonvolatile memory device.

While the present invention has been described in connection with the embodiment of the present invention illustrated in the accompanying drawings, it is not limited thereto. It will be apparent to those skilled in the art that various substitutions, modifications and changes may be made thereto without departing from the scope and spirit of the invention.

What is claimed is:

1. A nonvolatile memory device comprising:
a tunnel oxide layer on a semiconductor substrate;
a floating gate on the tunnel oxide layer;
a gate interlevel insulation layer on the floating gate;
a control gate on the gate interlevel insulation layer;
a source region at a side of the floating gate in the semiconductor substrate; and
a drain region at the other side of the floating gate in the semiconductor substrate,
wherein the floating gate comprises a first face adjacent to the source region and a second face adjacent to the drain region, the first face being curved toward the drain region.

2. The nonvolatile memory device as set forth in claim 1, wherein the device is configured as a split-gate type device.

3. The nonvolatile memory device as set forth in claim 2, wherein the second face is curved.

4. The nonvolatile memory device as set forth in claim 3, wherein the second face is curved toward the drain region.

5. The nonvolatile memory device as set forth in claim 3, wherein the second face is curved toward the source region.

6. The nonvolatile memory device as set forth in claim 3, wherein the control gate comprises a third face adjacent to the source region and a fourth face adjacent to the drain region, the fourth face being curved along a profile of the second face.

7. The nonvolatile memory device as set forth in claim 1, wherein the device is configured as a stacked-gate type device,
wherein the control gate comprises a third face adjacent to the source region and a fourth face adjacent to the drain region, the third face being aligned to the first face, and the fourth face being aligned to the second face.

8. The nonvolatile memory device as set forth in claim 7, wherein the second face is curved.

9. The nonvolatile memory device as set forth in claim 8, wherein the second face is curved toward the drain region.

10. The nonvolatile memory device as set forth in claim 8, wherein the second face is curved toward the source region.

11. The nonvolatile memory device as set forth in claim 1, further comprising an HSG film formed at top edges of the floating gate.

12. A method of fabricating a nonvolatile memory device, comprising:
forming field isolation layers in a semiconductor substrate to define active regions;
forming a tunnel oxide layer on the active regions;
forming a floating-gate layer over the semiconductor substrate;
forming a hard mask with openings partially exposing the floating-gate layer;
partially oxidizing the floating-gate layer through the openings to form a mask oxide layer;
removing the hard mask;
etching the floating-gate layer using the mask oxide layer as an etch mask to form a floating gate;
forming a gate interlevel insulation layer covering the floating gate;
forming a control gate layer;
etching the control gate layer to form a control gate that covers a partial top and sidewall of the floating gate and a part of the active region;
forming a source region at a side of the floating gate in the semiconductor substrate; and
forming a drain region at the other side of the floating gate in the semiconductor substrate,
wherein the floating gate comprises a first face adjacent to the source, the first face being curved and recessed to the drain region.

13. The method as set forth in claim 12, further comprising, before forming the hard mask, forming an HSG film on the floating-gate layer.

14. A method of fabricating a nonvolatile memory device, comprising:
forming field isolation layers in a semiconductor substrate to define active regions;
forming a tunnel oxide layer on the active regions;
forming a floating-gate layer over the semiconductor substrate;
patterning the floating-gate layer to expose the field isolation regions;
forming a gate interlevel insulation layer and a control gate layer over the semiconductor substrate;
patterning the control gate layer, the gate interlevel insulation layer, and the floating-gate layer in sequence to form a wordline crossing over the field isolation layers and a floating gate under the wordline;
forming a source region at a side of the floating gate in the semiconductor substrate; and
forming a drain region at the other side of the floating gate in the semiconductor substrate,
wherein the floating gate comprises a first face adjacent to the source, the first face being curved and recessed to the drain region.
